(19) United States
(12) Patent Application Publication
(10) Pub. No.: US 2026/0130215 A1
(43) Pub. Date: May 7, 2026

(54) THERMALLY ENHANCED FLIP CHIP DIES, MULTI-CHIP MODULE ASSEMBLY, AND METHODS OF FORMING SAME

(71) Applicant: SKYWORKS SOLUTIONS, INC., Irvine, CA (US)

(72) Inventors: Patrick Marcus Naraine, Boca Raton, FL (US); Guillaume Alexandre Blin, Carlisle, MA (US); Grant Darcy Poulin, Carp (CA); Raymond Mitchell Waugh, Milton, DE (US); Kezia Cheng, Lowell, MA (US)

(21) Appl. No.: 19/369,590

(22) Filed: Oct. 27, 2025

Related U.S. Application Data
(60) Provisional application No. 63/716,767, filed on Nov. 6, 2024.
(60) Provisional application No. 63/716,764, filed on Nov. 6, 2024.

(51) Int. Cl. H01L 23/373; H01L 21/78; H01L 23/00; H01L 23/31; H01L 23/48; H01L 23/544; H01L 25/065; H01L 25/16

(52) U.S. Cl. CPC H10W 40/258; H10P 54/00; H10W 20/20; H10W 46/00; H10W 74/114; H10W 90/00; H10W 72/07251; H10W 72/20

(57) ABSTRACT

A method of fabricating flip chip dies comprising fabricating or providing a wafer including one or more component circuits, a front side having a plurality of metal bumps, a back side, and one or more wafer streets for dicing the wafer; mounting the wafer on a temporary wafer carrier via the metal bumps, depositing a copper layer on the back side of the wafer; defining one or more streets in the copper layer, the one or more streets being aligned with the one or more wafer streets, dicing the wafer into a plurality of singulated flip chip dies each having a component circuit of the one or more component circuits, and removing the plurality of singulated flip chip dies from the temporary wafer carrier. A method for fabricating a multi-chip module assembly, and a multi-chip module assembly is also provided.

### CROSS-REFERENCE TO RELATED APPLICATIONS

This application claims priority under 35 U.S.C. § 119(e) to U.S. Provisional Patent Application Ser. No. 63/716,764, titled “METHOD OF FABRICATING A THERMALLY ENHANCED MULTI-CHIP MODULE ASSEMBLY,” filed Nov. 6, 2024, and to U.S. Provisional Patent Application Ser. No. 63/716,767, titled “METHOD OF FABRICATING THERMALLY ENHANCED FLIP CHIP DIES AND MULTI-CHIP MODULE ASSEMBLY,” filed Nov. 6, 2024, the entire content of each being incorporated herein by reference for all purposes.

### BACKGROUND

### Field of Technology

The present disclosure relates generally to methods of fabricating flip chip dies and a multi-chip module assembly. More specifically, the present disclosure relates to methods of fabricating flip chip dies and a multi-chip module assembly having improved thermal performance.

### Description of the Related Technology

Flip chip die are typically directly connected to carriers (e.g., substrates, circuit boards, and the like) via conductive bumps that are placed on the surface of the dies. In contrast to traditional wire bonding techniques, interconnection between the flip chip die and the carrier occurs via the conductive bumps. The die having conductive bumps is flipped and placed face down so that conductive bumps are directly attached to the carrier, thereby forming a flip chip package or a module.

One advantage of flip chip packages is that they are typically smaller than traditional wire bonded packages with the same functionality. The size of such packages can be significant for portable electronic devices, such as cellular phones, smart phones, portable MP3 players, and the like. As sizes of flip chip packages continue to decrease, improving their thermal performance becomes even more significant. Therefore, there exists a need to provide efficient top-side cooling of a flip chip die.

### SUMMARY

According to one aspect of the present disclosure, there is provided a method of fabricating flip chip dies. The method comprises fabricating or providing a wafer including one or more component circuits, a front side having a plurality of metal bumps, a back side, and one or more wafer streets for dicing the wafer, mounting the wafer on a temporary wafer carrier via the metal bumps, depositing a copper layer on the back side of the wafer, defining one or more streets in the copper layer, the one or more streets being aligned with the one or more wafer streets, dicing the wafer into a plurality of singulated flip chip dies each having a component circuit of the one or more component circuits, and removing the plurality of singulated flip chip dies from the temporary wafer carrier.

In one example, the method further comprises opening the one or more wafer streets and the one or more streets in the copper layer prior to dicing the wafer.

In one example, depositing the copper layer on the back side of the wafer includes depositing the copper layer using a copper plating process or a screen printing process.

In one example, the one or more component circuits comprises one or more power amplifier circuits, switch circuits, control circuits, or filter circuits.

In one example, depositing the copper layer using the screen printing process includes depositing the copper layer as two or more layers.

In one example, depositing the copper layer and defining the one or more streets in the copper layer includes selectively depositing the copper layer on the back side of the wafer to define the one or more streets in the copper layer.

In one example, defining the one or more streets in the copper layer includes using a wafer mask to define the one or more streets.

In one example, defining the one or more streets in the copper layer comprises laser drilling the one or more streets in the copper layer.

In one example, the copper layer has a thickness of at least 50 micrometers.

In one example, the wafer includes one or more through wafer vias configured to electrically couple the front side of the wafer to the back side of the wafer.

In one example, mounting the wafer on the temporary wafer carrier includes temporarily adhering the metal bumps to the temporary wafer carrier with an adhesive.

In one example, the temporary wafer carrier is a silicon temporary wafer carrier.

In one example, the wafer includes a compound semiconductor or a piezoelectric layer.

According to another aspect of the present disclosure, there is provided a method of fabricating or providing a singulated flip chip die including one or more component circuit, the singulated flip chip die including a front side having a plurality of metal bumps, and a back side having a copper layer, mounting the singulated flip chip die on a multi-chip module via the metal bumps, overmolding the multi-chip module, a thickness of the overmold at least covering the copper layer, and reducing the thickness of the overmold such that a surface of the copper layer is exposed through the overmold.

In one example, fabricating or providing the singulated flip chip die includes fabricating or providing a wafer including the component circuit, the front side having a plurality of metal bumps, the back side, and one or more wafer streets for dicing the wafer, mounting the wafer on a temporary wafer carrier via the metal bumps, depositing the copper layer on the back side of the wafer, defining one or more streets in the copper layer, the one or more streets being aligned with the one or more wafer streets, dicing the wafer into a plurality of singulated flip chip dies each having a component circuit of the one or more component circuits, and removing the plurality of singulated flip chip dies from the temporary wafer carrier.

In one example, reducing the thickness of the overmold includes back-grinding the overmold such that the surface of the copper layer is exposed.

In one example, the method further comprises applying a conductive epoxy or solder pre-form to the exposed copper layer, and mounting a heat spreading mechanism on the exposed copper layer via the conductive epoxy or solder pre-form.

In one example, the heat spreading mechanism is a heat sink.

In one example, the method further comprises coupling an air-flow mechanism to the heat sink, the air-flow mechanism being configured to provide forced air-flow to the heat sink.

According to another aspect of the present disclosure, there is provided a multi-chip module assembly comprising a flip chip die including a front side having a plurality of metal bumps and a back side having a copper layer, and a multi-chip module, the flip chip die being mounted on the multi-chip module via the plurality of metal bumps, and an overmold having a thickness being such that a surface of the copper layer is exposed through the overmold.

According to another aspect of the present disclosure, there is provided a method for fabricating a multi-chip module assembly. The method comprises mounting a flip chip die including a component circuit, a front side having a plurality of metal bumps, and a back side on a multi-chip module via the plurality of metal bumps, stacking a silicon die on the back side of the flip chip die, overmolding the multi-chip module, a thickness of the overmold at least covering the silicon die, reducing the thickness of the overmold such that a surface of the silicon die is exposed through the overmold, and depositing or attaching a metal layer at least covering a front side of the multi-chip module, the front side including the surface of the silicon die.

In one example, the method further comprises grinding the silicon die to a predetermined thickness prior to stacking the silicon die.

In one example, the method further comprises dicing the silicon die to a predetermined length and width prior to stacking the silicon die.

In one example, one or both of the predetermined length and width is greater than a respective length and width of the flip chip die.

In one example, stacking the silicon die on the back side of the flip chip die includes adhering the silicon die to the flip chip die with a thermally conductive adhesive.

In one example, the silicon die is an undoped silicon die.

In one example, the metal layer is a copper layer.

In one example, depositing or attaching the copper layer includes using a copper plating process or a screen printing process.

In one example, depositing or attaching the metal layer further comprises depositing or attaching the metal layer over and enclosing the multi-chip module, the metal layer being in contact with a peripheral boundary of the multi-chip module.

In one example, reducing the thickness of the overmold includes back-grinding the overmold such that the surface of the silicon die is exposed.

In one example, the component circuit comprises one of a power amplifier circuit, a switch circuit, a control circuit, or a filter circuit.

In one example, the flip chip die includes one or more through wafer vias configured to electrically couple the front side of the flip chip die to the back side of the flip chip die.

In one example, the flip chip die includes a compound semiconductor or a piezoelectric layer.

According to another aspect of the present disclosure, there is provided a multi-chip module assembly. The multi-chip module assembly comprises a flip chip die including a component circuit, a front side having a plurality of metal bumps, and a back side, and a multi-chip module, the flip chip die being mounted on the multi-chip module via the plurality of metal bumps, a silicon die stacked on the back side of the flip chip die, an overmold, a thickness of the overmold being such that a surface of the silicon die is exposed through the overmold, and a metal layer at least covering a front side of the multi-chip module, the front side including the surface of the silicon die.

In one example, one or both of a length and width of the silicon die is greater than a respective length and width of the flip chip die.

In one example, the silicon die is adhered to the flip chip die with a thermally conductive adhesive.

In one example, the metal layer is a copper layer.

In one example, the metal layer is over and encloses the multi-chip module, the metal layer being in contact with a peripheral boundary of the multi-chip module.

In one example, the component circuit comprises one of a power amplifier circuit, a switch circuit, a control circuit, or a filter circuit.

According to another aspect of the present disclosure, there is provided a wireless electronic device. The wireless electronic device comprises an antenna and a front end module. The front end module includes a multi-chip module assembly, the multi-chip module assembly having a flip chip die including a component circuit, a front side having a plurality of metal bumps, and a back side, and a multi-chip module, the flip chip die being mounted on the multi-chip module via the plurality of metal bumps, a silicon die stacked on the back side of the flip chip die, an overmold, a thickness of the overmold being such that a surface of the silicon die is exposed through the overmold, and a metal layer at least covering a front side of the multi-chip module, the front side including the surface of the silicon die.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1A illustrates a step of a method of fabricating flip chip dies in accordance with aspects of the present disclosure;

FIG. 1B illustrates a step of a method of fabricating flip chip dies in accordance with aspects of the present disclosure;

FIG. 1C illustrates a step of a method of fabricating flip chip dies in accordance with aspects of the present disclosure;

FIG. 1D illustrates a step of a method of fabricating flip chip dies in accordance with aspects of the present disclosure;

FIG. 1E illustrates a step of a method of fabricating flip chip dies in accordance with aspects of the present disclosure;

FIG. 2 illustrates flowchart of a method of fabricating flip chip dies in accordance with aspects of the present disclosure;

FIG. 3A illustrates a step of a method of fabricating a multi-chip module assembly in accordance with aspects of the present disclosure;

FIG. 3B illustrates a step of a method of fabricating a multi-chip module assembly in accordance with aspects of the present disclosure;

FIG. 3C illustrates a step of a method of fabricating a multi-chip module assembly in accordance with aspects of the present disclosure;

FIG. 4 illustrates flowchart of a method of fabricating a multi-chip module assembly in accordance with aspects of the present disclosure;

FIG. 5A illustrates a step of a method of fabricating a multi-chip module assembly in accordance with aspects of the present disclosure;

FIG. 5B illustrates a step of a method of fabricating a multi-chip module assembly in accordance with aspects of the present disclosure;

FIG. 5C illustrates a step of a method of fabricating a multi-chip module assembly in accordance with aspects of the present disclosure;

FIG. 6 illustrates flowchart of a method of fabricating a multi-chip module assembly in accordance with aspects of the present disclosure;

FIG. 7 illustrates a top view of a flip chip package having a plurality of flip chip dies in accordance with aspects of the present disclosure; and

FIG. 8 illustrates an electronic device in accordance with aspects of the present disclosure.

### DETAILED DESCRIPTION

Typically, systems such as massive multiple input multiple output (M-MIMO) systems (for example, 5G M-MIMO systems) require high power amplifier modules with a small footprint, high efficiency, and low cost. The inventors of the present disclosure have appreciated that, since M-MIMO systems use large quantities of power amplifier units which may all be co-located in the antenna housing, there is no space for conventional air-cooled systems. The inventors have also appreciated that existing systems allowing only thermal cooling from the “under-side” of a package and through the PCB may lead to a very large thermal resistance.

Aspects and embodiments described herein provide methods, modules, and devices for improving thermal performance of flip chip dies and multi-chip modules including one or more flip chip dies according to embodiments described herein. In particular, aspects and embodiments described herein provide improved thermal performance of component modules such as power amplifier modules at relatively low cost when compared with modules employing forced air-cooling and/or expensive copper slugs buried inside circuit boards. Improvement of thermal performance encompasses improvement of thermal dissipation (e.g., cooling) and reduction of thermal resistance. Improved thermal performance can result in a more efficient operation and, thereby, in conservation of power (e.g., battery power).

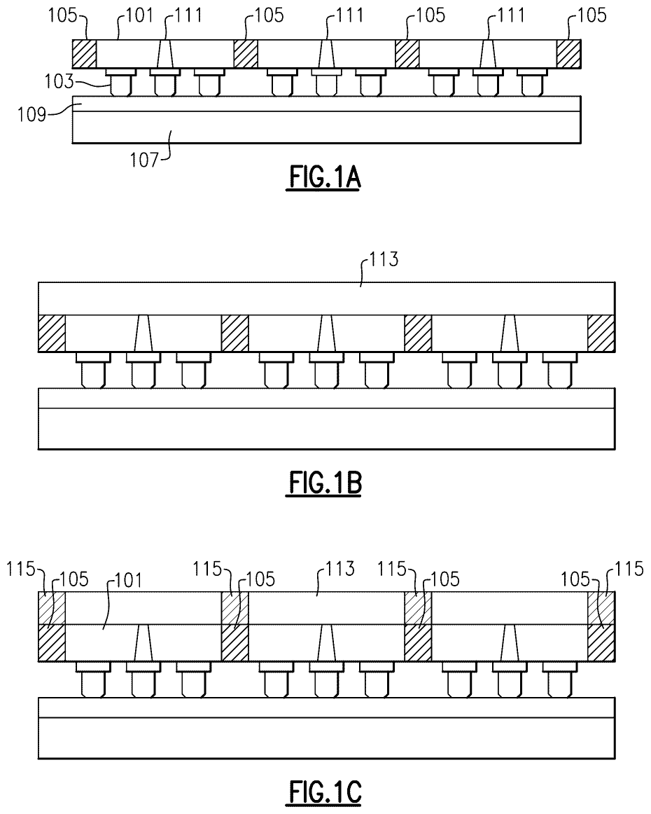

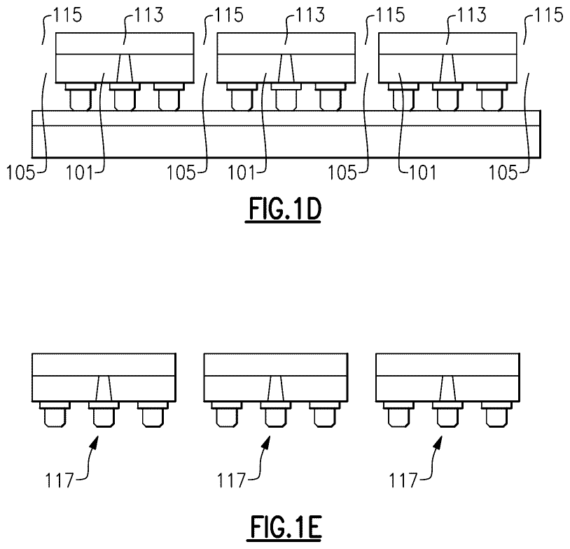

Embodiments of the present disclosure will be described with reference to the accompanying FIGS. 1 to 8. For clarity of the Figures, reference numerals in relation to features repeatedly illustrated across several Figures are repeated only where useful for discussion of the embodiments.

FIGS. 1A to 1E illustrate an embodiment of a method for fabricating flip chip dies in accordance with aspects of the disclosure.

FIG. 1A illustrates a step of a method of fabricating flip chip dies in accordance with aspects of the disclosure. In an embodiment, the method comprises fabricating or providing a wafer 101. The wafer 101 includes one or more electrical components or component circuits which may be, for example, power amplifier circuits, switch circuits, control circuits, or filter circuits. The filter circuits may comprise an acoustic wave filter such as a surface acoustic wave (SAW) or bulk acoustic wave (BAW) filters. In such embodiments, the flip chip die may include a piezoelectric layer. In some embodiments, the wafer includes a compound semiconductor such as gallium nitride (GaN), gallium arsenide (GaAs), indium phosphide (InP), or silicon carbide (SiC). The wafer 101 also includes a front side having a plurality of metal bumps 103 or bump connectors which may be pillar or solder connections. The wafer 101 further includes a back side, and one or more wafer streets 105 for dicing the wafer 101.

The wafer 101 is mounted on a temporary carrier wafer 107 via the metal bumps 103. In this embodiment, the wafer 101 is mounted on the temporary carrier wafer 107 via the metal bumps 103 using an adhesive 109, and the temporary carrier wafer 107 is a silicon temporary carrier wafer. However, it will be appreciated that the wafer 101 may be mounted on the temporary carrier wafer 107 by any suitable method, and the temporary carrier wafer 107 may comprise any suitable material.

The wafer 101 also includes one or more through wafer vias 111 configured to electrically couple the front side of the wafer 101 to the back side of the wafer 101. For example, the vias 111 may be placed so as to contact one or more of the metal bumps 103. The through wafer vias or through holes may be provided by laser drilling. In some embodiments, the vias may be filled with copper, such as thick film copper by a screen printing process.

FIG. 1B illustrates another step of the method in which a copper layer 113 is deposited on the back side of the wafer 101 illustrated in FIG. 1A. The copper layer 113 may be deposited on the back side of the wafer 101 using a copper plating process. In an alternative embodiment, the copper layer 113 may be deposited using a screen printing process in which the copper layer 113 is deposited as two or more layers. For example, the screen printing process may include thick film technology in which an additive process involves depositing several copper layers to form the copper layer, or may include depositing the copper layer 113 as a copper paste. The copper layer 113 is relatively thick and may be deposited with a thickness of at least 50 micrometers. In some embodiments, the deposited copper layer 113 may have a thickness of 100 micrometers. In some embodiments, the through wafer vias may be filled with a thick copper film by the screen printing process while screen printing the copper layer.

FIG. 1C illustrates a further step of the method comprising defining one or more streets 115 in the copper layer 113, the one or more streets 115 in the copper layer 113 being aligned with the one or more wafer streets 105. In one embodiment, defining the one or more streets in the copper layer 113 includes using a wafer mask to define the one or more streets 115. However, it will be appreciated that, in some embodiments, the streets 115 may be defined using another process. For example, depositing the copper layer 113 may include selectively depositing the copper layer 113 on the back side of the wafer 101 to define the one or more streets 115.

FIG. 1D illustrates a further step of the method comprising opening the one or more wafer streets 105 in the wafer 101 and the one or more streets 115 in the copper layer 113 prior to dicing the wafer 101.

As illustrated in FIG. 1E, the wafer 101 is diced into a plurality of singulated flip chip dies 117 through the opened streets, each flip chip die 117 having a component circuit. Lastly, the plurality of singulated flip chip dies 117 are removed from the temporary carrier wafer 107.

Thus, there is provided a low cost method for fabricating flip chip dies 117, each die having a copper layer 113 on the back side of the flip chip die 117. The provision of the copper layer 113 provides improved thermal performance of the flip chip dies. Improvement of thermal performance encompasses improvement of thermal dissipation (e.g., cooling) and reduction of thermal resistance. Improved thermal performance can result in a more efficient operation and, thereby, in conservation of power (e.g., battery power).

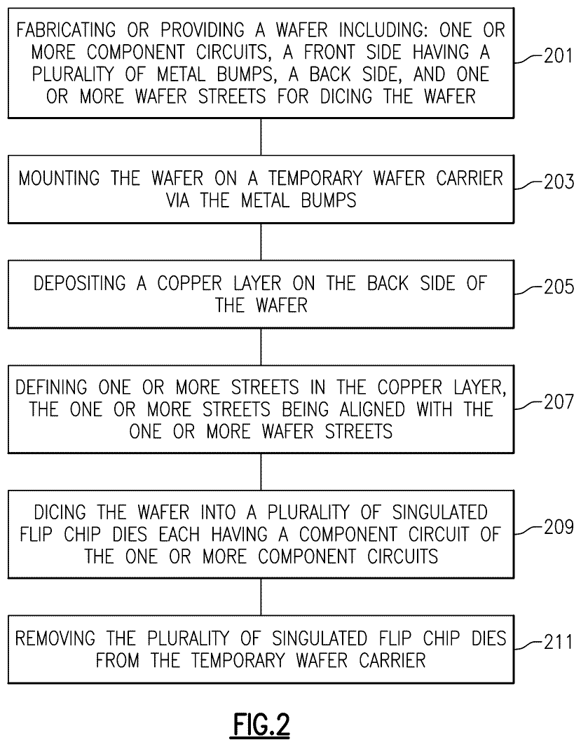

FIG. 2 illustrates a flow chart of the method for fabricating flip chip dies in accordance with embodiments of the present disclosure.

At step 201, the method comprises fabricating or providing a wafer including one or more component circuits, a front side having a plurality of metal bumps, a back side, and one or more wafer streets for dicing the wafer.

At step 203, the wafer is mounted on a temporary wafer carrier via the metal bumps.

At step 205, a copper layer is deposited on the back side of the wafer.

At step 207, one or more streets are defined in the copper layer, the one or more streets being aligned with the one or more wafer streets.

At step 209, the wafer is diced into a plurality of singulated flip chip dies each having a component circuit of the one or more component circuits.

At step 211, the plurality of singulated flip chip dies are removed from the temporary carrier wafer.

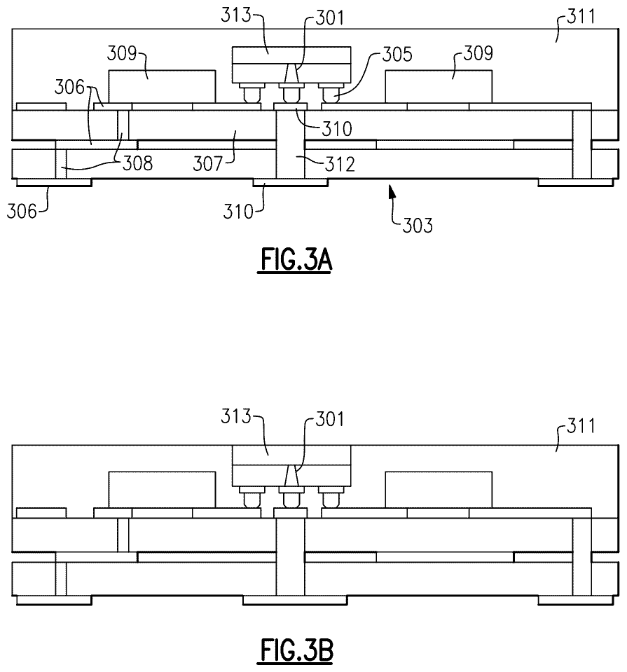

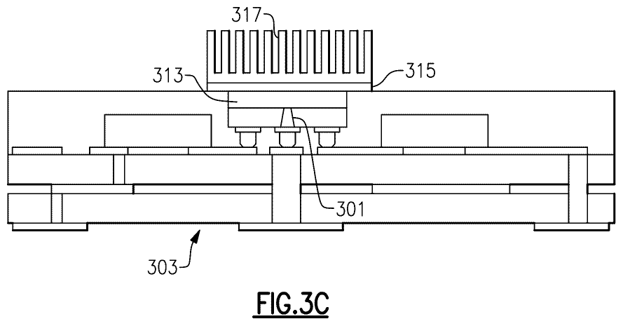

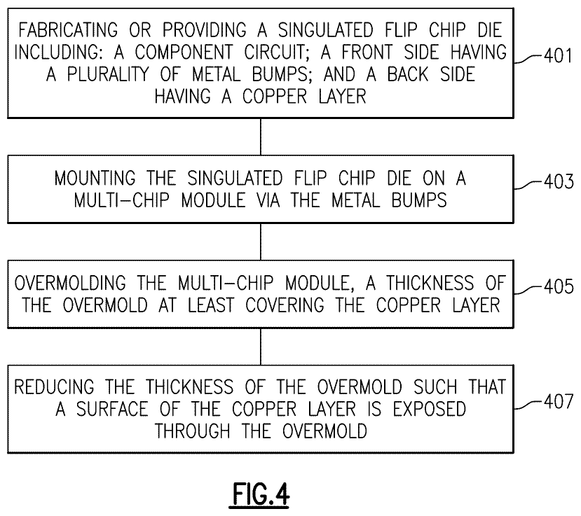

A method for fabricating a multi-chip module (MCM) assembly in accordance with aspects of the present disclosure will now be described with respect to FIGS. 3A to 3C.

A first step of the method includes fabricating or providing a singulated flip chip die including a component circuit, a front side having a plurality of metal bumps, and a back side having a copper layer. Such a flip chip die may be fabricated in the manner according to embodiments described herein. Alternatively, the fabrication and provision of the flip chip die may be a separate process, which may comprise one or more flip chip dies in a tape and reel, which may then be used during the assembly of the MCM.

The singulated flip chip die 301, which may be the singulated flip chip die illustrated in FIGS. 1A to 1E, is mounted on the MCM 303 via the metal bumps 305 in a flip chip configuration. For example, the MCM may comprise a substrate 307 and the singulated flip chip die 301 is flipped and mounted to the substrate 307 of the MCM 303 via the metal bumps 305 such that the metal bumps make contact with the substrate, achieving electrical connection between the flip chip die 301 and the substrate 307. This may include picking and placing the flip chip die 301. The mounting of the flip chip die 301 on the MCM 303 can yield an assembly that may also be referred to as a flip chip package.

The MCM may also include one or more pads and corresponding vias to provide electrical connection through at least part of the MCM. For example, the MCM may include one or more signal pads 306, one or more corresponding signal vias 308, one or more ground pads 310, and one or more corresponding ground vias 312. The metal bumps 305 may be mounted to the substrate via one or more signal pads 306 and a ground pad 312, thereby achieving the electrical connection between the flip chip die 301 and the substrate 307. Such pads and vias may be provided in a typical manner understood by the skilled person.

In some embodiments, the method includes mounting one or more surface mount components 309 directly on the substrate 307 using surface mount technology (SMT). In other embodiments, the method includes mounting the flip chip die 301 to an MCM comprising one or more surface mount components 309 mounted on the substrate 307. Components can include passive components, such as resistors, capacitors, inductors, diodes, and active components such as transistors, or a combination thereof.

The method further includes overmolding the MCM 303. The overmold 311 may be constructed using an epoxy resin. The overmold structure 311 can enclose the exposed sides of the flip chip die 301 mounted on the substrate, including left, right, and top sides. In some embodiments, the overmold 311 may be constructed having a thickness of approximately 50 micrometers above the copper layer 313 of the flip chip die 301.

In a next step illustrated in FIG. 3B, the method includes reducing the thickness of the overmold 311 such that a surface of the copper layer 313 of the flip chip die 301 is exposed through the overmold 311. For example, a portion of the overmold 311 is removed by back-grinding the overmold 311 to an appropriate depth to expose the copper layer 313.

Thus, an MCM is fabricated including a flip chip die 301 having a copper layer 313 as described in relation to the embodiment illustrated in FIG. 1E, thereby providing improved thermal performance of the flip chip die and the fabricated MCM.

In some embodiments having reduced the thickness of the overmold 311, a conductive epoxy layer 315 is applied to the exposed copper layer 313 and a heat spreading mechanism 317 is mounted on the exposed copper layer 313 via the conductive epoxy layer 315 as illustrated in FIG. 3C. It will be appreciated that the conductive epoxy 315 may alternatively be any suitable material for mounting the heat spreading mechanism 317 such as a solder pre-form. In some embodiments, the heat spreading mechanism can be a heat sink. By providing the heat spreading mechanism, the thermal performance of the flip chip die 301 and the MCM 303 can be further improved. In some embodiments, the thermal performance may be yet further improved by coupling an air-flow mechanism to the heat sink, the air-flow mechanism being configured to provide forced air-flow to the heat sink.

There is thus provided an MCM assembly or flip chip package according to the described method of fabrication having improved thermal performance including improvement of thermal dissipation (e.g., cooling) and reduction of thermal resistance at a low cost, resulting in a more efficient operation and, thereby, in conservation of power.

FIG. 4 illustrates a flow chart of the method for fabricating a multi-chip module assembly in accordance with embodiments of the present disclosure.

At step 401, the method comprises fabricating or providing a singulated flip chip die including a component circuit, a front side having a plurality of metal bumps, and a back side having a copper layer.

At step 403, the singulated flip chip die is mounted on a multi-chip module via the metal bumps.

At step 405, the method comprises overmolding the multi-chip module, a thickness of the overmold at least covering the copper layer.

At step 407, the thickness of the overmold is reduced such that a surface of the copper layer is exposed through the overmold.

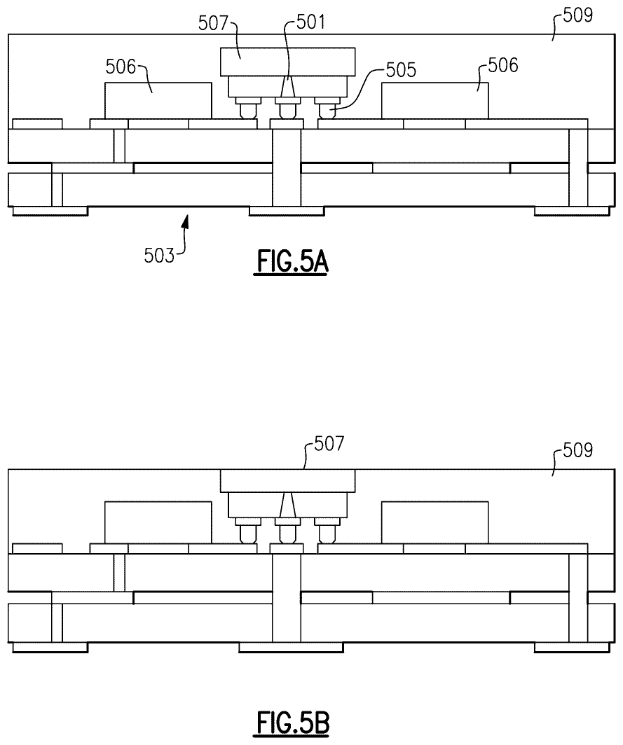

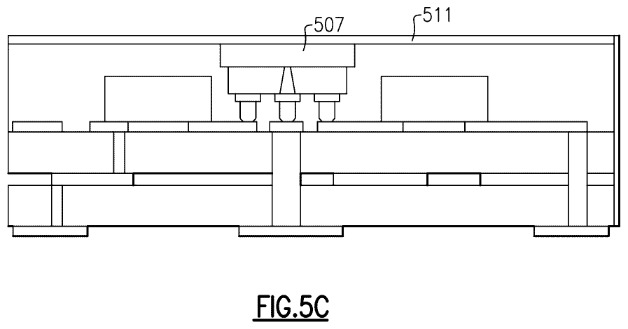

Another method for fabricating a multi-chip module (MCM) assembly in accordance with aspects of the present disclosure will now be described with respect to FIGS. 5A to 5C. As will be described, in some respects, the method is similar to the method described in relation to FIGS. 3A and 3B. However, in this example, the copper layer of the flip chip die is replaced with a silicon layer.

In more detail, the method comprises mounting a flip chip die 501 including a component circuit, a front side having a plurality of metal bumps 505, and a back side on a multi-chip module 503 via the plurality of metal bumps 505. The flip chip die 501 may be mounted in the manner described in relation to FIG. 3A. For example, the MCM 503 may include a substrate and the flip chip die 501 is mounted to the substrate in a flip chip configuration. The MCM 503 may similarly include one or more signals pads, corresponding signal vias, one or more ground pads, and corresponding ground vias as described in relation to FIG. 3A. The MCM 503 may similarly include one or more surface mount components 506 directly on the substrate of the MCM 505 using surface mount technology (SMT), and the method may include mounting such surface mounting components 506.

The method further includes stacking a silicon die 507 on the back side of the flip chip die 501. The silicon die 507 may an undoped silicon die, and may be adhered to the flip chip die 501 with a thermally conductive adhesive. In a similar manner to the copper layer of the flip chip described in relation to previous embodiments, the silicon die 507 acts as a heat sink to provide improved thermal performance of the flip chip die and MCM. The stacking of the silicon die 507 is advantageously performed during assembly of the MCM, meaning no additional processing of the flip chip die 501 is required.

In some embodiments, the method includes grinding the silicon die 507 to a predetermined thickness prior to stacking the silicon die 507 on the flip chip die 501. In some embodiments, the silicon die 507 is diced to a predetermined length and width prior to stacking the silicon die 507, where the predetermined length and width may be greater than a respective length and width of the flip chip die 501 to maximize heat spreading.

As illustrated in FIG. 5A, the method includes overmolding the multi-chip module, a thickness of the overmold at least covering the silicon die. The overmolding may be performed in the manner described in relation to FIG. 3A. As illustrated in FIG. 5B, the method also includes reducing the thickness of the overmold 509 such that a surface of the silicon die 507 is exposed through the overmold 509. This step may similarly be performed in the manner described in relation to FIG. 3B including back-grinding the overmold 509. However, in this example, a surface of the silicon die 507 is exposed through the overmold 509.

As illustrated in FIG. 5C, the method further includes depositing or attaching a metal layer 511 at least covering a front side of the multi-chip module, the front side including the surface of the silicon die 507. In some embodiments, the metal layer 511 is a copper layer, which may be deposited using a copper plating process or a screen printing process. The MCM may ultimately be diced to provide the MCM assembly, and the metal layer 511 may be deposited or attached to the front side of the MCM before dicing which can improve bonding of the silicon die 507 to the top of the MCM or flip chip package.

In some embodiments, the metal layer 511 is deposited or attached over and enclosing the MCM, the metal layer 511 being in contact with a peripheral boundary of the MCM. This not only improves the thermal bonding of the silicon die 507, but also provides radio frequency (RF) and/or electromagnetic interference (EMI) shielding to the MCM or package. The metal layer 511 may cover at least a portion of one or more sides of the MCM.

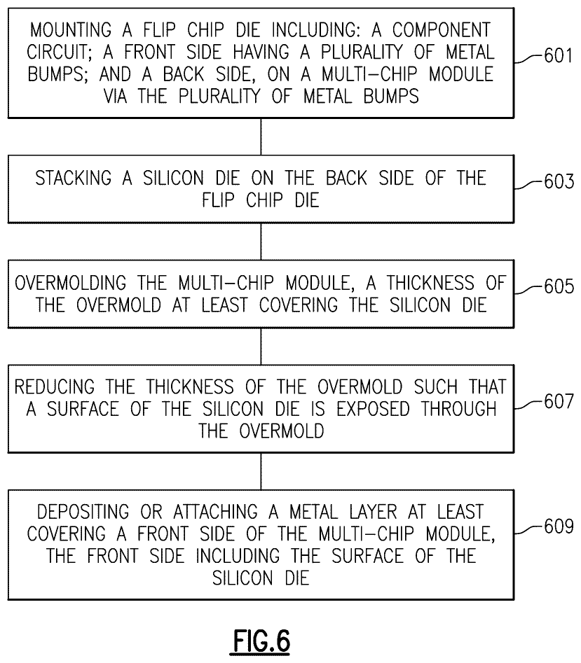

FIG. 6 illustrates a flow chart of the method for fabricating a multi-chip module assembly in accordance with embodiments of the present disclosure.

At step 601, the method comprises mounting a flip chip die including a component circuit, a front side having a plurality of metal bumps, and a back side on a multi-chip module via the plurality of metal bumps.

At step 603, a silicon die is stacked on the back side of the flip chip die.

At step 605, the method comprises overmolding the multi-chip module, a thickness of the overmold at least covering the silicon die.

At step 607, the method comprises reducing the thickness of the overmold such that a surface of the silicon die is exposed through the overmold.

At step 609, the method comprises depositing or attaching a metal layer at least covering a front side of the multi-chip module, the front side including the surface of the silicon die.

There is therefore provided a multi-chip module assembly comprising a flip chip die including a component circuit, a front side having a plurality of metal bumps, and a back side, a multi-chip module, the flip chip die being mounted on the multi-chip module via the plurality of metal bumps, a silicon die stacked on the back side of the flip chip die, an overmold, a thickness of the overmold being such that a surface of the silicon die is exposed through the overmold, and a metal layer at least covering a front side of the multi-chip module, the front side including the surface of the silicon die.

Although methods of fabricating a single MCM assembly is described, it will be appreciated that the process can be used to fabricate a plurality of MCM assemblies or flip chip packages. In addition, although the MCM assemblies described include a single flip chip die, multiple dies may also be included.

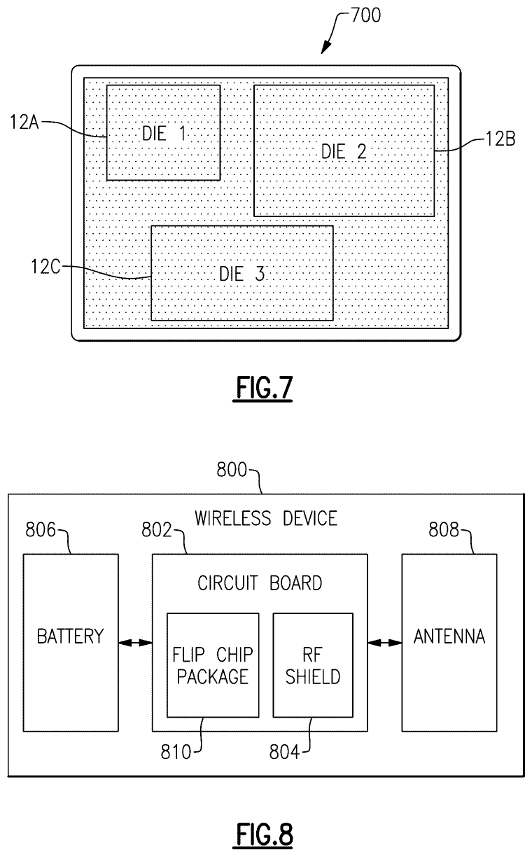

For example, FIG. 7 illustrates a flip chip package 700 having a plurality of flip chip dies in accordance with aspects of the present disclosure. In particular, FIG. 7 shows a top view of the package 700. In some implementations, the package 700 can be a front-end module for a wireless communication device, such as a cellular phone. Each die may comprise a component circuit or electrical component. For example, die 12A can be a power amplifier, die 12B can be a switch (e.g., a RF Tx/Rx switch), and die 12C can be a controller. Dies 12A, 12B, and 12C can be mounted on a common substrate (not shown), and the package includes an overmold structure to protect the dies. Further, copper layers are be formed on the surfaces of dies 12A, 12B, 12C in accordance with embodiments described herein, the copper layers of each die being exposed through the overmold. As described, the copper layers of each die can improve thermal performance (e.g., thermal dissipation) of the package 700. It will be appreciated that the flip chip package 700 may instead have dies having silicon layers in accordance with embodiments described herein. In certain embodiments, the package 700 can include additional dies or include fewer dies than is illustrated in FIG. 7.

An MCM in accordance with aspects of the present disclosure may be provided in a front end module, which may be provided in an electronic device such as a wireless electronic device. An example wireless electronic device according to embodiments described herein comprises an antenna and a front end module including a multi-chip module assembly. The multi-chip module assembly has a flip chip die including a component circuit, a front side having a plurality of metal bumps, and a back side, a multi-chip module, the flip chip die being mounted on the multi-chip module via the plurality of metal bumps, a silicon die stacked on the back side of the flip chip die, an overmold, a thickness of the overmold being such that a surface of the silicon die is exposed through the overmold, and a metal layer at least covering a front side of the multi-chip module, the front side including the surface of the silicon die.

FIG. 8 illustrates an electronic device such as a wireless electronic device 800 in accordance with aspects of the present disclosure. In some embodiments, the device 800 can be a portable wireless device, such as a cellular phone. The device 800 can include a battery 806 configured to supply power to the device, a circuit board 802 configured to provide support for and interconnect various electronic components, and an antenna 808 configured to receive and transmit wireless signals. The electronic device 800 can include a number of additional components, such as a display processor, central processor, user interface processor, memory, etc.

The circuit board 802 (e.g., a phone board) can include a metal layer which here is an RF shield 804 configured to provide radio frequency (RF) and/or electromagnetic interference (EMI) shielding for the electronic components of the circuit board 802, such as a flip chip package 810. The RF shield 804 can be positioned to shield from interference caused by signals received and/or transmitted by the antenna 808. In some embodiments, the RF shield 804 can be positioned to cover the entire or substantially entire circuit board 802 in order to shield the board from interference. In various embodiments, the RF shield 804 can additionally be positioned to cover the battery 806 in order to shield it from interference. The flip chip package 810 can include one or more flip chip dies according to aspects of the present disclosure. Further, the flip chip package 810 can include a copper layer or silicon layer (not shown) as described above. Such layers can improve thermal performance (e.g., thermal dissipation) of the package 810.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

The teachings of the invention provided herein can be applied to other systems, not necessarily the system described above. The elements and acts of the various embodiments described above can be combined to provide further embodiments.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method of fabricating flip chip dies, the method comprising:
fabricating or providing a wafer including one or more component circuits, a front side having a plurality of metal bumps, a back side, and one or more wafer streets for dicing the wafer;
mounting the wafer on a temporary wafer carrier via the metal bumps;
depositing a copper layer on the back side of the wafer;
defining one or more streets in the copper layer, the one or more streets being aligned with the one or more wafer streets;
dicing the wafer into a plurality of singulated flip chip dies each having a component circuit of the one or more component circuits; and
removing the plurality of singulated flip chip dies from the temporary wafer carrier.

2. The method of claim 1 further comprising opening the one or more wafer streets and the one or more streets in the copper layer prior to dicing the wafer.

3. The method of claim 1 wherein depositing the copper layer on the back side of the wafer includes depositing the copper layer using a screen printing process.

4. The method of claim 3 wherein depositing the copper layer using the screen printing process includes depositing the copper layer as two or more layers.

5. The method of claim 1 wherein the one or more component circuits comprises one or more power amplifier circuits, switch circuits, control circuits, or filter circuits.

6. The method of claim 1 wherein depositing the copper layer and defining the one or more streets in the copper layer includes one of selectively depositing the copper layer on the back side of the wafer to define the one or more streets in the copper layer or using a wafer mask to define the one or more streets.

7. The method of claim 1 wherein defining the one or more streets in the copper layer comprises laser drilling the one or more streets in the copper layer.

8. The method of claim 1 wherein the copper layer has a thickness of at least 50 micrometers.

9. The method of claim 1 wherein mounting the wafer on the temporary wafer carrier includes temporarily adhering the metal bumps to the temporary wafer carrier with an adhesive.

10. The method of claim 1 wherein the wafer includes a compound semiconductor or a piezoelectric layer.

11. A method of fabricating a multi-chip module assembly, the method comprising:
mounting a flip chip die including a component circuit, a front side having a plurality of metal bumps, and a back side on a multi-chip module via the plurality of metal bumps;
stacking a silicon die on the back side of the flip chip die;
overmolding the multi-chip module, a thickness of the overmold at least covering the silicon die;
reducing a thickness of the overmold such that a surface of the silicon die is exposed through the overmold; and
depositing or attaching a metal layer at least covering a front side of the multi-chip module, the front side including the surface of the silicon die.

12. The method of claim 11 further comprising grinding the silicon die to a predetermined thickness and dicing the silicon die to a predetermined length and width prior to stacking the silicon die, one or both of the predetermined length and width being greater than a respective length and width of the flip chip die.

13. The method of claim 11 wherein stacking the silicon die on the back side of the flip chip die includes adhering the silicon die to the flip chip die with a thermally conductive adhesive.

14. The method of claim 11 wherein the metal layer is a copper layer.

15. The method of claim 14 wherein depositing or attaching the copper layer includes using a copper plating process or a screen printing process.

16. The method of claim 11 wherein depositing or attaching the metal layer further comprises depositing or attaching the metal layer over and enclosing the multi-chip module, the metal layer being in contact with a peripheral boundary of the multi-chip module.

17. The method of claim 11 wherein reducing the thickness of the overmold includes back-grinding the overmold such that the surface of the silicon die is exposed.

18. The method of claim 11 wherein the component circuit comprises one of a power amplifier circuit, a switch circuit, a control circuit, or a filter circuit.

19. The method of claim 11 wherein the flip chip die includes one or more through wafer vias configured to electrically couple the front side of the flip chip die to the back side of the flip chip die.

20. The method of claim 11 wherein the flip chip die includes a compound semiconductor or a piezoelectric layer.
